(19) United States
(12) Patent Application Publication
(10) Pub. No.: US 2016/0064636 A1
(43) Pub. Date: Mar. 3, 2016

(54) THERMOELECTRIC GENERATION APPARATUS FOR VEHICLE

(71) Applicant: Hyundai Motor Company, Seoul (KR)

(72) Inventors: Su Jung Noh, Seoul (KR); Kyong Hwa Song, Seoul (KR); Han Saem Lee, Seoul (KR); In Chang Chu, Seoul (KR); Gyong Bok Kim, Seoul (KR); In Woong Lyo, Suwon (KR); Jin Woo Kwak, Gyeongsan (KR)

(21) Appl. No.: 14/683,568

(22) Filed: Apr. 10, 2015

(30) Foreign Application Priority Data
Sep. 1, 2014 (KR) 10-2014-0115234

(51) Int. Cl. H01L 35/30; F02B 63/04

(52) U.S. Cl. CPC H01L 35/30; F02B 63/04

(57) ABSTRACT

A thermoelectric generation apparatus for a vehicle using waste heat of an engine is provided. The thermoelectric generation apparatus includes a conduction block that has a high thermal conductivity and is disposed between an engine and an exhaust manifold. A first thermoelectric element module is configured to generate an electromotive force from a difference between temperatures of opposite ends of the first thermo electric element. In addition, the first thermoelectric element is disposed at one side of the conduction block. Accordingly, thermoelectric generation efficiency of the first thermoelectric element module is increased by minimizing heat loss of the waste heat gas discharged from the engine.

### CROSS-REFERENCE TO RELATED APPLICATION(S)

This application claims under 35 U. S. C. §119(a) the benefit of Korean Patent Application No. 10-2014-0115234 filed on Sep. 1, 2014, the entire contents of which are incorporated herein by reference.

### BACKGROUND

1. Technical Field

The present invention relates a thermoelectric generation apparatus for a vehicle using waste heat of an engine and more particularly, to a thermoelectric generation apparatus for a vehicle, which improves power generation output using waste heat discharged from an engine without heat loss.

2. Background Art

Generally, a thermoelectric generation technology for vehicles refers to a technology of mounting thermoelectric elements through which electrons move due to a temperature gradient to an exhaust system of an engine, which is a high temperature heat source of a vehicle, together with a cooling system to generate electricity. The thermoelectric elements generate an output due to a temperature difference between a high temperature part (e.g., a heat source part) and a low temperature part (e.g., a cooling part), and may directly convert heat into electricity without using a mechanical driving unit.

However, since the thermoelectric elements increase power generation output when a temperature difference between the high temperature part and the low temperature part increases, energy generation efficiency may not be substantial when the temperature difference is minimal. Many of the thermoelectric apparatuses that have been developed employ a thermoelectric element module within an exhaust system, in which thermoelectric generation efficiency may decrease since waste heat of a highest temperature generated by an engine may not be used. In addition, since the thermoelectric generation apparatuses employ a thermoelectric element module suitable for a temperature area band of an exhaust system, an increase in output may be limited and a plate-shaped thermoelectric element module may be difficult to mount a circular curved exhaust pipe.

### SUMMARY

The present invention provides a thermoelectric generation apparatus for a vehicle, which may improve thermoelectric power generation efficiency by mounting a conduction block of a substantially high thermal conductivity between an engine and a tip end of an exhaust manifold. In addition, the present invention provides a thermoelectric generation apparatus for a vehicle, which uses waste heat, generated by the engine and discharged to an exhaust manifold, from an engine, wherein a conduction block that has a substantially high thermal conductivity is installed between an engine and an exhaust manifold. In addition, a first thermoelectric element module configured to generate an electromotive force using a difference between temperatures of opposite ends the first thermoelectric element module is mounted at one side of the conduction block, whereby thermoelectric generation efficiency of the first thermoelectric element module may increase by minimizing heat loss of the waste heat gas discharged from the engine.

A cooling unit for cooling one side surface of the first thermoelectric element module may be stacked on the first thermoelectric element module and the first thermoelectric element module may be fixedly supported on the conduction block by coupling the cooling unit to one side of the conduction block. A second thermoelectric element module may be stacked on the cooling unit to contact the cooling unit and the second thermoelectric module may be fixedly supported on the cooling unit by staking a support plate coupled to the cooling unit on the second thermoelectric element module.

The thermoelectric generation apparatus may include a heat transfer element configured to transfer the heat of the conduction block to the second thermoelectric element module. One end (e.g., a first end) of the heat transfer unit may be stacked between the conduction block and the first thermoelectric element module and an opposite side (e.g., a second end) of the heat transfer unit may be stacked between the second thermoelectric element module and the support plate.

The first thermoelectric module and the second thermoelectric module may include thermoelectric elements that have different driving temperature bands. The first thermoelectric module may include thermoelectric elements that have a driving temperature band greater than a driving temperature band of thermoelectric elements of the second thermoelectric element module. The conduction block may have a plurality of gas flow apertures to allow waste heat gas discharged from the engine to flow, and the gas flow apertures may extend to an exhaust manifold. Further, the conduction block may have a polyhedral shape for easier mounting of the thermoelectric element module. In addition, the conduction block may be formed of cast iron or stainless steel that has a heat resisting property and a durability against a substantially high temperature waste gas discharged from the engine. The heat transfer element may be a heat pipe. The thermoelectric generation apparatus for a vehicle according to an exemplary embodiment of the present invention may have the following advantages.

1. Since waste gas discharged from an engine may be used in a substantially high temperature state without loss of heat, a thermoelectric element module that has a higher power generation output compared to the related art may be used.

2. Thermoelectric power generation efficiency and power generation output may improve using a thermoelectric element module that use a substantially high temperature and a thermoelectric element module that uses a substantially low temperature. Notably, a low temperature range may be about room temperature to 300° C., a mid temperature may be about 300 to 400° C., and a high temperature may be about 500 to 600° C. However, the high temperature is merely exemplary and may be greater than 600° C.

3. A thermoelectric element module may be mounted without considering a contact surface of an exhaust pipe, a thermoelectric element module may be more easily mounted.

### BRIEF DESCRIPTION OF THE DRAWINGS

The above and other features of the present invention will now be described in detail with reference to exemplary embodiments thereof illustrated the accompanying drawings which are given herein below by way of illustration only, and thus are not limitative of the present invention, and wherein:

FIG. 1 is an exemplary sectional view showing a thermoelectric generation apparatus for a vehicle according to an exemplary embodiment of the present invention;

FIG. 2 is an exemplary enlarged view of section A of FIG. 1 according to an exemplary embodiment of the present invention; and

FIG. 3 is an exemplary view showing a state when a part of the thermoelectric generation apparatus for a vehicle is mounted between an engine and an exhaust manifold according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment. In the figures, reference numbers refer to the same or equivalent parts of the present invention throughout the several figures of the drawing.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Hereafter, the present invention will be described so that those skilled in the art to which the present invention pertains can easily carry out the invention.

The present invention provides a thermoelectric generation apparatus that may convert a substantially high temperature waste heat generated by an engine of a vehicle into electrical energy and may improve thermoelectric generation efficiency and fuel ratio of an engine by using exhaust heat discharged from the engine in a highest temperature state.

As shown in FIGS. 1 to 3, a thermoelectric generation apparatus for a vehicle according to an exemplary embodiment of the present invention may use waste heat generated by an engine 10 and discharged from an exhaust manifold 20. In addition, a conduction block 110 that has a high thermal conductivity may be disposed between the engine 10 and the exhaust manifold 20. Further, a thermoelectric element module may contact a first side surface of the conduction block 110, where thermoelectric generation may have a greater efficiency, using waste heat of a highest temperature discharged from the engine 10. The thermoelectric generation of a higher efficient may be achieved by minimizing heat loss of waste heat gas (e.g., exhaust gas that includes waste heat discharged from the engine).

The thermoelectric element module 121 and 122 may include a plurality of thermoelectric elements configured to generate thermoelectric power. Although not shown in the drawings, the thermoelectric elements may include wires through which electromotive forces generated by the thermoelectric elements may be output, and since the configuration of the thermoelectric element module that use the thermoelectric elements as a basic configuration is a well-known to those skilled in the art, a detailed description thereof will be omitted. As generally known in the art, a thermoelectric element is an element that uses a Seebeck effect that corresponds to when an electromotive force is generated by a temperature difference between opposite ends thereof, and an electromotive force is generated when opposite ends of a thermoelectric element have different temperatures.

The conduction block may be formed of a refractory (e.g., capable of refracting) and durable material which may not be deformed by waste heat gas of a substantially high temperature discharged from an engine and satisfies a material property combination with the exhaust manifold 20. For example, the conduction block may be manufactured of a metal, such as cast iron or stainless steel. In addition, the conduction block 110 may have a polyhedral shape (e.g., a hexahedral shape) such that the thermoelectric element module 121 may be mounted without considering a contact surface with an exhaust pipe. In other words, to more easily attach the thermoelectric element module 121 to the conduction block, the conduction block 110 may be adhered to the engine 10. Further, the conduction block may include a gas flow aperture 111 configured to deliver waste gas discharged from the engine 10 to the exhaust manifold 20.

The gas flow aperture 111 may extend from one surface to an opposite surface of the conduction block 110 to allow waste heat gas to flow from an end of the engine 10 to the exhaust manifold 20. The conduction block 110 may be fixedly mounted to an outer wall of the engine using an engaging bolt or the like, and the size of the conduction block 110 may be modified based on the size, shape, number of the thermoelectric modules.

Referring to FIG. 1, at least one thermoelectric element module 121 may contact upper and lower surfaces of the conduction block 110 and the thermoelectric element modules 121 may be mounted to any surfaces of the conduction block 110 except surfaces of the conduction block 110 adhered to the engine 10 and connected to the exhaust manifold 20. Although not shown in the drawings, sealing spaces between the conduction block 110 and the engine 10 and between the conduction block 110 and the exhaust manifold 20 may prevent waste heat gas leakage. As shown in FIG. 1, a plurality of thermoelectric generation units 120 that include the thermoelectric element modules 121 and 122, a cooling unit 123, and a heat pipe 124 may be attached to an upper surface and a lower surface of the conduction block 110, respectively.

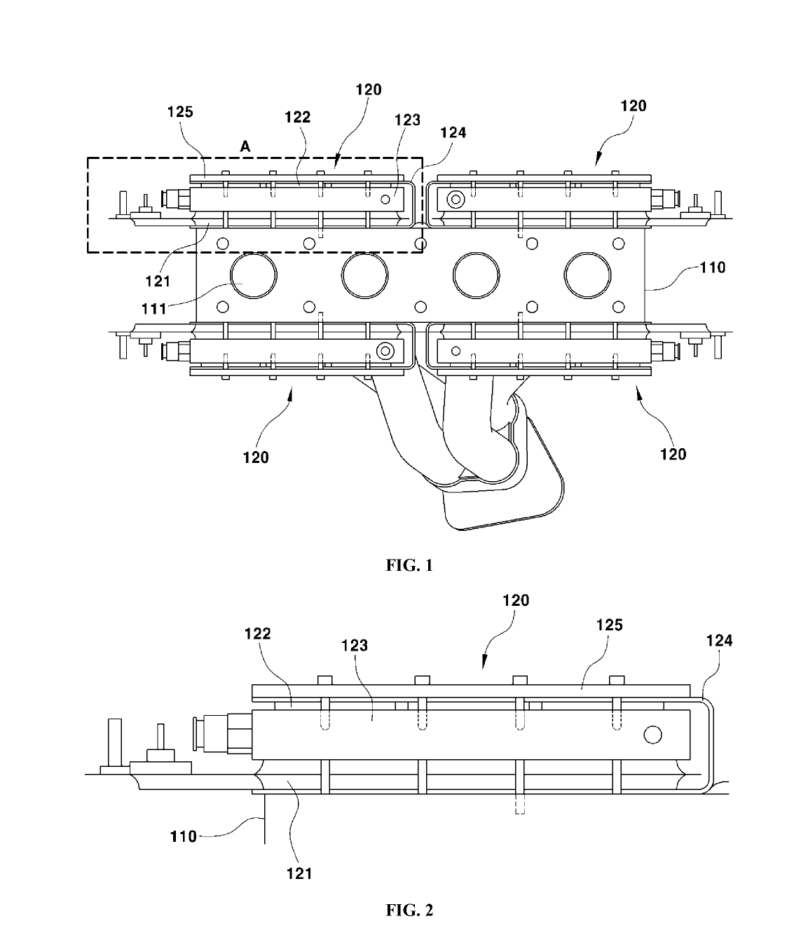

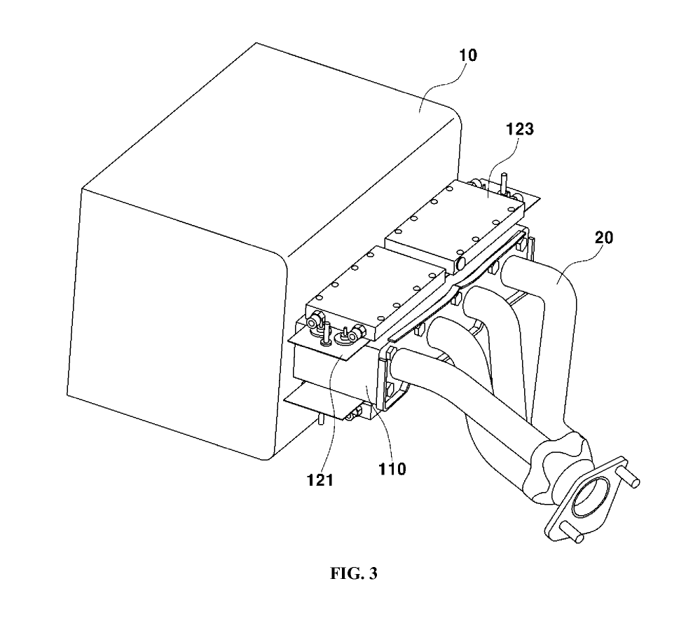

Referring to FIG. 2, a first thermoelectric element module 121 that corresponds to a high temperature area (e.g., that has a substantially high driving temperature band) may be stacked on one surface of the conduction block 110. In addition, a cooling unit 123 configured to cool surfaces of the thermoelectric element modules 121 and 122 may be stacked on the first thermoelectric element module 121 and a second thermoelectric element module 121 that corresponds to a low temperature area (e.g., that has a low driving temperature band) may be stacked on the cooling unit 123. Further, a support plate 125 may be stacked on the second thermoelectric element module 122.

The cooling unit 123 may be coupled to one surface of the conduction module 110 using an engaging bolt and the support plate 125 may be coupled to a first side of the cooling unit 123 on the second thermoelectric module 122 using an engaging bolt. Accordingly, the first thermoelectric element module 122 may be fixedly supported between the conduction block 110 and the cooling unit 123 and the second thermoelectric element module 122 may be fixedly supported between the cooling unit 123 and the support plate 125. In other words, the cooling unit 123 may be engaged to the first side of the conduction block 110 to fixedly support the first thermoelectric module 121 on the conduction block 110, and the support plate 125 may be engaged to one side of the cooling unit 123 to fixedly support the second thermoelectric element module 122 on the cooling unit 123. In particular, the support plate 125 may be formed with a thermally non-conductive material.

The cooling unit 123 may use a water cooling jacket as a liquid cooler to cool side surfaces of the first and second thermoelectric element modules 121 and 122. A heat pipe 124 that operates as a heat transfer element may be mounted to transfer heat of the conduction block 110 to the second thermoelectric element module 122. The heat pipe 124 may have a substantially U shape. In particular, a first end (e.g., a heat absorbing part) may be stacked and adhered between the conduction block 110 and the first thermoelectric element module 121 and a second end (e.g., a heat dissipating part) may be stacked and adhered between the second thermoelectric element module 122 and the support plate 125.

When a volatile liquid (e.g., water or alcohol) is introduced into and sealed within a decompressed (e.g., vacuumed) pipe and the first side of the pipe is heated, the liquid may evaporate and flow to the second side. Alternatively, when heat is dissipated from the opposite side of the pipe and the gas condenses, the volatile liquid may return to the first side of the pipe due to a capillary phenomenon.

Accordingly, the heat pipe 124 may be disposed such that when the first end is heated by the conduction block 110, the volatile liquid in the interior of the heat pipe 124 may evaporate and flow to the second end. Further, the volatile liquid may condense at the second end to allow heat and thermal energy to be transferred to the second thermoelectric element module 122.

The thermoelectric generation apparatus according to an exemplary embodiment of the present invention may increase power generation by using waste heat gas of a high temperature discharged from the engine 10 without loss of heat. In addition, the thermoelectric generation apparatus may increase power generation output and improve thermoelectric power generation efficiency by using the thermoelectric element modules 121 and 122 that have different driving temperature areas simultaneously. In particular, the first thermoelectric element module 121 may be disposed to generate an electromotive force by a Seebeck effect due to the temperature difference between the two surfaces thereof. Further, the second thermoelectric element module 122 may be disposed to generate an electromotive force by a Seebeck effect due to the temperature difference between the two surfaces thereof.

As generally known in the art, the thermoelectric elements have different usable driving temperature areas (e.g., temperature bands) based the types thereof, and the first thermoelectric element module and the second thermoelectric element module may be thermoelectric elements of suitable temperature areas, respectively. For example, the first thermoelectric element module 121 may include thermoelectric elements for substantially high temperature, which are used in a greater driving temperature area than the first thermoelectric element module 122. In other words, the first thermoelectric element module 121 may have a higher thermoelectric performance than the second thermoelectric element module 122.

As described above, since the thermoelectric generation apparatus according to an exemplary embodiment of the present invention may use waste heat discharged from an engine at a highest temperature state without loss of heat, a thermoelectric element module that corresponds to a higher temperature area as compared to the related art may be used and thermoelectric power generation efficiency may increase. In addition, thermoelectric power output may also increase by using both a thermoelectric element module that corresponds to a middle/high temperature area and a thermoelectric module that corresponds to a normal temperature (or low temperature) area.

Although exemplary embodiments of the present invention have been described in detail, the scope of the present invention is not limited thereto but various modifications and improvements made by those skilled in the art using the basic concept of the present invention defined in the claims also fall within the scope of the present invention.

What is claimed is:

1. A thermoelectric generation apparatus for a vehicle, comprising:
a conduction block that has a substantially high thermal conductivity and is disposed between an engine and an exhaust manifold;
a first thermoelectric element module configured to generate an electromotive force from a difference between temperatures of opposite ends of the first thermoelectric element module and disposed at one side of the conduction block.

2. The thermoelectric generation apparatus of claim 1, further comprising:
a cooling unit configured to cool a first side surface of the first thermoelectric element module and is stacked on the first thermoelectric element module,
wherein the first thermoelectric element module is fixedly supported on the conduction block by coupling the cooling unit to one side of the conduction block.

3. The thermoelectric generation apparatus of claim 2, further comprising:
a second thermoelectric element module disposed on the cooling unit to contact the cooling unit,
wherein the second thermoelectric module is fixedly supported on the cooling unit by staking a support plate coupled to the cooling unit on the second thermoelectric element module.

4. The thermoelectric generation apparatus of claim 2, further comprising:
a second thermoelectric element module disposed on the cooling unit to contact the cooling unit; and
a heat transfer unit configured to transfer the heat of the conduction block to the second thermoelectric element module,
wherein the second thermoelectric module is fixedly supported on the cooling unit by coupling a support plate to the cooling unit on the second thermoelectric element module, and
wherein a first end of the heat transfer element is disposed between the conduction block and the first thermoelectric element module and a second end of the heat transfer element is disposed between the second thermoelectric element module and the support plate.

5. The thermoelectric generation apparatus of claim 4, wherein the first thermoelectric module and the second thermoelectric module include a plurality of thermoelectric elements that have different driving temperature bands.

6. The thermoelectric generation apparatus of claim 4, wherein the first thermoelectric module includes:
thermoelectric elements that have a driving temperature band greater than a driving temperature band of thermoelectric elements of the second thermoelectric element module.

7. The thermoelectric generation apparatus of claim 1, wherein the conduction block includes:
a plurality of gas flow apertures configured to allow waste heat gas discharged from the engine to flow,
wherein the gas flow apertures extend to an exhaust manifold.

8. The thermoelectric generation apparatus of claim 1, wherein the conductive block has a polyhedral shape.

9. The thermoelectric generation apparatus of claim 1, wherein the conduction block is formed of cast iron or stainless steel.

10. The thermoelectric generation apparatus of claim 4, wherein the heat transfer element is a heat pipe.

11. A vehicle comprising the apparatus of claim 1.
